(19) United States
(12) Patent Application Publication
(10) Pub. No.: US 2012/0118618 A1
(43) Pub. Date: May 17, 2012

(54) Printed circuit board and method for manufacturing the same

(75) Inventor: Byung Seung Min, (US)

(73) Assignee: Samsung Electro-Mechanics Co., Ltd., Suwon (KR)

(21) Appl. No.: 12/929,480

(22) Filed: Jan. 27, 2011

(30) Foreign Application Priority Data
Nov. 15, 2010 (KR) 10-2010-0113410

(51) Int. Cl. H05K 1/09; H05K 3/10; H05K 1/11

(52) U.S. Cl. 174/257; 174/266; 29/846

(57) ABSTRACT

Disclosed herein are a printed circuit board and a method for manufacturing the same. The method for manufacturing a printed circuit board includes: (a) forming at least one plate through hole penetrating through an insulating layer; (b) forming pattern grooves for implementing inner layer circuits on both surfaces of the insulating layer; and (c) filling the plate through hole and the pattern grooves with a conductive material. The method for manufacturing a printed circuit board may provide the printed circuit board having excellent heat radiating characteristics and reduce process cost.

### CROSS REFERENCE(S) TO RELATED APPLICATIONS

This application claims the benefit under 35 U.S.C. Section [120, 119, 119(e)] of Korean Patent Application Serial No. 10-2010-0113410, entitled “Printed Circuit Board and Method for Manufacturing the Same” filed on Nov. 15, 2010, which is hereby incorporated by reference in its entirety into this application.

### BACKGROUND OF THE INVENTION

1. Technical Field

The present invention relates to a printed circuit board and a method for manufacturing the same, and more particular, to a printed circuit board and a method for manufacturing the same having excellent heat radiating characteristics.

2. Description of the Related Art

Recently, with the increase in the demand for semiconductor chips having high performance such as rapid operating speed, large capacity, and the like, the demand for packages capable of mounting a large number of input/output pins (I/O pins) in a printed circuit board (PCB) has also increased. Accordingly, technology has quickly changed from a wire bonding scheme or a plastic ball grid array (PBGA) scheme to a flip chip bonding (FCB) scheme.

Increasing the input/output pins in order to raise performance of the package is advantageous in terms of speed or capacity. However, in order to increase the input/output pins, the printed circuit board should have high integration, micro pattern, and the like. As a result, the number of components mounted on .the printed circuit board has rapidly increased. As a large number of components are integrated at narrow intervals, a heat radiating problem newly occurs. According to the related art, in order to solve the heat radiating problem, methods of mounting a heat spreader made of copper (Cu), Invar, or the like, on a package after completing packaging or applying a heat sink to a mother board have been mainly used. The methods are advantageous in terms of heat radiating characteristics; however, the number of processes is increased and compactness may not be implemented due to the increase in the package volume. As another method, there is a method of applying a metal core to the printed circuit board. However, this method may be applied only to a flip chip bonding package with a copper clad laminate (CCL) of the printed circuit board having a thickness of 0.1 t or less and has difficulty in being applied to a flip chip bonding package with a copper clad laminate having a thickness of 0.4 t or more. Herein, t indicates mm.

### SUMMARY OF THE INVENTION

An object of the present invention is to provide a unit having excellent heat radiating characteristics capable of rapidly radiating heat generated in a printed circuit board and chips mounted thereon.

Another object of the present invention is to provide a unit capable of reducing the number of processes for manufacturing a printed circuit board.

Another object of the present invention is to provide a unit capable of reducing process cost for manufacturing a printed circuit board.

According to an exemplary embodiment of the present invention, there is provided a method for manufacturing a printed circuit board, including: (a) forming at least one plate through hole penetrating through an insulating layer; (b) forming pattern grooves for implementing inner layer circuits on both surfaces of the insulating layer; and (c) filling the plate through hole and the pattern grooves with a conductive material.

According to another exemplary embodiment of the present invention, there is provided a printed circuit board, including: an insulating layer; at least one plate through hole formed to penetrate through the insulating layer and filled with a conductive material; and inner circuits buried in both surfaces of the insulating layer.

### BRIEF DESCRIPTION OF THE DRAWINGS

FIGS. 1 to 4 are views sequentially showing a method for manufacturing a printed circuit board according to an exemplary embodiment of the present invention; and

FIG. 5 is a view showing an example of a configuration of a printed circuit board formed by the process in FIG. 1.

### DESCRIPTION OF THE PREFERRED EMBODIMENTS

Hereinafter, exemplary embodiments of the present invention will be described with reference to the accompanying drawings. However, the exemplary embodiments are described by way of examples only and the present invention is not limited thereto.

In describing the present invention, when a detailed description of well-known technology relating to the present invention may unnecessarily make unclear the spirit of the present invention, a detailed description thereof will be omitted. Further, the following terminologies are defined in consideration of the functions in the present invention and may be construed in different ways by the intention of users and operators. Therefore, the definitions thereof should be construed based on the contents throughout the specification.

As a result, the spirit of the present invention is determined by the claims and the following exemplary embodiments may be provided to efficiently describe the spirit of the present invention to those skilled in the art.

Hereinafter, a method for manufacturing a printed circuit board according to exemplary embodiments of the present invention will be described with reference to the accompanying drawings.

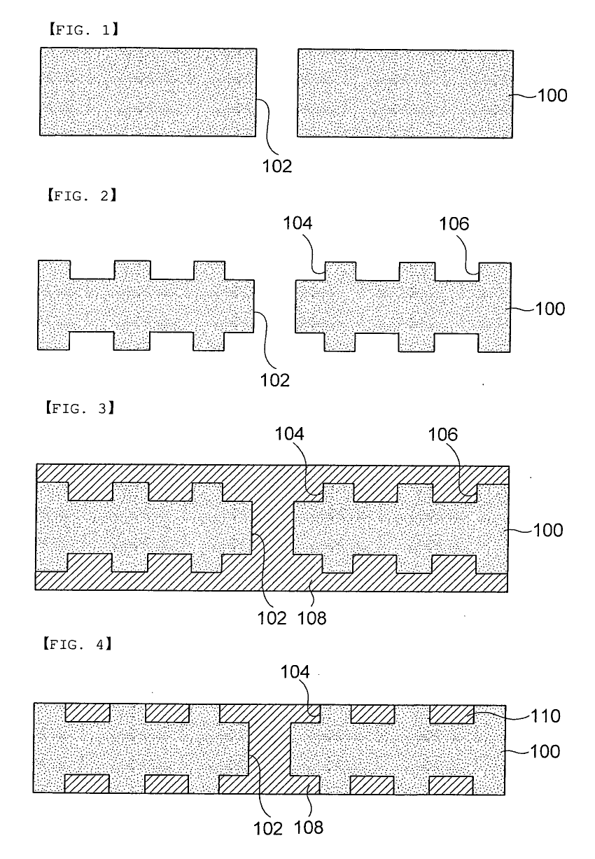

FIGS. 1 to 4 are views sequentially showing a method for manufacturing a printed circuit board according to an exemplary embodiment of the present invention.

First, as shown in FIG. 1, a plate through hole (PTH) 102 is formed in a first insulating layer 100. Herein, the plate through hole 102 is formed in order to electrically interconnect circuit patterns to be formed on an upper surface and a lower surface of the first insulating layer 100. The plate through hole 102 is formed by mechanical drilling or laser drilling. If the laser drilling is used, a laser drilling using CO₂ is mainly used; however, a laser drilling using ultraviolet-Yag (UV-Yag) may also be used. In addition, the plate through hole 102 may be formed by various methods such as a pressing method, a laser machining method, or the like.

Next, referring to FIG. 2, plate through hole lands 104 and pattern grooves 106 for inner layer circuit are formed on the upper and lower surfaces of the first insulating layer 100 by a damascene process using a laser processing method, an exposing method, or the like. Herein, the plate through hole land 104 is an additional margin area which is formed for more stable connection of a via hole to be formed in a subsequent process and the plate through hole 102 when they are electrically interconnected. As shown in FIG. 2, the plate through hole land 104 enlarges an area of the plate through hole 102 exposed in the upper and lower surfaces of the first insulating layer 100. Meanwhile, the pattern groove 106 is a pattern engraved in the first insulating layer 100 in order to implement the inner layer circuit.

Thereafter, referring to FIG. 3, copper (cu) ink 108 having high conductivity is injected into the plate through hole 102 and the pattern groove 106 to be filled therein and is applied on the upper and lower surfaces of the first insulating layer 100. Then, the copper ink 108 is heat-cured. Meanwhile, conductive ink, conductive paste, or the like, having high conductivity may be used, in addition to the copper ink 108.

Next, referring to FIG. 4, the upper and lower surfaces of the first insulating layer 100 are scratch polished and sanded to remove copper remaining on the surfaces of the first insulating layer 100 other than the plate through hole 102 and the inner layer circuit 100. Accordingly, the plate through hole 102 remains in the state of being filled with copper, and the inner side circuits 110 are formed in both surfaces of the first insulating layer 100. As a subsequent process of the method for manufacturing a printed circuit board, a general process may be used. Therefore, the description thereof will be omitted.

Meanwhile, the damascene process generally indicates a process of making a groove in a substrate, electroplating the groove, and then performing polishing. However, in the present invention, the damascene process indicates a process of making a groove in the first insulating layer 100 and filling the groove with copper ink. Although the inner layer circuit 110 may be formed in the groove of the first insulating layer 100 using an electroplating method, a method of using the copper ink may reduce cost as compared to the electroplating method.

As such, in the present invention, the pattern groove 106 for inner layer circuit 110 is made in the first insulating layer 100, and the copper ink 108 is simultaneously injected into the pattern groove 106 and the plate through hole 102, thereby making it possible to fill the plate through hole 102 with the conductive material and form the inner layer circuit 100 through a single process.

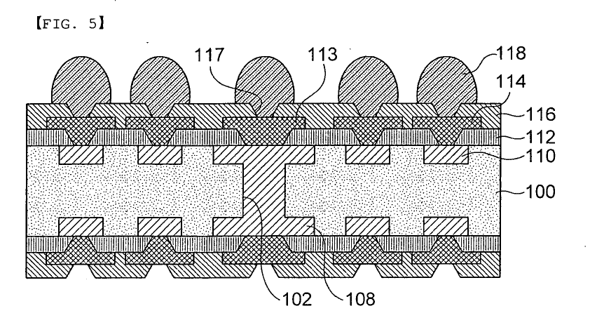

FIG. 5 is a view showing an example of a configuration of a printed circuit board formed by the process in FIG. 1.

Referring to FIG. 5, a printed circuit board includes a first insulating layer 100, a plate through hole 102, inner layer circuits 110, second insulating layers 112, outer layer circuits 114, third insulating layers 116, and bumps 118.

First, at least one plate through hole 102 is formed in the first insulating layer 100 while penetrating through the first insulating layer 110 and the plate through hole 102 is filled with a conductive material such as copper ink. In addition, the inner layer circuit 110 formed by filling a pattern groove with the copper ink is formed in the first insulating layer 100. At this time, the plate through hole 102 and the pattern groove for inner layer circuit are simultaneously filled with the copper ink. That is, the plate through hole 102 is filled with the conductive material and the inner layer circuit 100 is formed through a single process.

Next, the second insulating layer 112 is formed on the inner layer circuit 110 and the first insulating layer 100, and at least one first via hole 113 is formed to penetrate through the second insulating layer 112. The first via hole 113 is a path for electrically connecting the inner layer circuit 110 to the outer layer circuit 114 and is formed with the outer layer circuit 114. At this time, the outer layer circuit 114 may be made of copper having high conductivity, and an electroplating method may be applied to the outer layer circuit 114.

Thereafter, the third insulating layer 116 is formed on the outer layer circuit 114 and the second insulating layer 112. Herein, the third insulating layer 116, which is a solder resist, may be made of a resin, which is an insulating material.

Then, at least one second via hole 117 is formed to penetrate through the third insulating layer 116. The second via hole 117 is a path for electrically connecting a bump 118 to the outer layer circuit 114. The second via hole 117 is provided with the bumps 118. Although not shown, the bumps 118 are in contact with the pins of a chip mounted on the printed circuit board to serve as a path for exchanging signals between the pins of the chip and the inner layer circuit 110 and the outer layer circuit 114.

Summing up, the printed circuit board according to the exemplary embodiment of the present invention buries the circuit pattern in the surface of the first insulating layer 100 to form the inner layer circuit, such that a copper clad laminate having copper foils coated on both surfaces of the first insulating layer needs not to be used. Accordingly, it is possible to reduce an additional cost for the copper foil. In addition, the plate through hole 102 is filled with the copper, which is a material having high conductivity, such that the entire plate through hole 102 becomes a signal transfer path as well as a heat transfer path between the inner layer circuit 110 and the outer layer circuit 114 formed on both surfaces of the first insulating layer 100. In the case in which heat generated in the chip mounted on the printed circuit board is not rapidly radiated together with the heat generated in the printed circuit board when the circuit is operated, performance of the chip may be deteriorated. However, as in the present invention, when the entire plate through hole 112 is used as the heat transfer path, heat radiating characteristics are improved, thereby making it possible to rapidly radiate the heat of the printed circuit board and the chip.

In addition, the copper ink is also injected into the pattern groove for inner layer circuit, while being injected into the plate through hole 102, thereby making it possible to fill the plate through hole 102 with the conductive material and form the inner layer circuit 100 through a single process.

As set forth above, according to the exemplary embodiment of the present invention, the inner layer circuit is buried in the surface of the insulating layer, such that the copper clad laminate having copper foils coated on both surfaces of the insulating layer, needs not to be used, thereby making it possible to reduce the additional cost for the copper foil.

In addition, according to the exemplary embodiment of the present invention, the damascene process is used to form the pattern groove for inner layer circuit in the insulating layer, thereby making it possible to fill the plate through hole with the conductive material and form the inner layer circuit through a single copper injection process.

Further, according to the exemplary embodiment of the present invention, the entire plate through hole interconnecting the outer layer circuit and the inner layer circuit formed on both surfaces of the insulating layer is filled with the conductive material to be used as the heat transfer path, thereby making it possible to improve heat radiating characteristics of the printed circuit board.

Furthermore, according to the exemplary embodiment of the present invention, when applying the damascene process, the electroplating process included in an existing damascene process may be replaced by the copper ink injection process, thereby making it possible to reduce the process cost.

Although the exemplary embodiments of the present invention have been disclosed for illustrative purposes, those skilled in the art will appreciate that various modifications are possible, without departing from the scope and spirit of the invention.

Accordingly, the scope of the present invention is not construed as being limited to the described embodiments but is defined by the appended claims as well as equivalents thereto.

What is claimed is:

1. A method for manufacturing a printed circuit board, comprising:
(a) forming at least one plate through hole penetrating through an insulating layer;
(b) forming pattern grooves for implementing inner layer circuits on both surfaces of the insulating layer; and
(c) filling the plate through hole and the pattern grooves with a conductive material.

2. The method for manufacturing a printed circuit board according to claim 1, wherein the plate though hole and the pattern groove are filled with the conductive material by the same process.

3. The method for manufacturing a printed circuit board according to claim 1, wherein the inner layer circuits are formed to be buried in the surface of the insulating layer.

4. The method for manufacturing a printed circuit board according to claim 1, wherein the conductive material is a conductive paste or a conductive liquid.

5. The method for manufacturing a printed circuit board according to claim 4, wherein the conductive liquid is copper ink.

6. The method for manufacturing a printed circuit board according to claim 1, wherein the pattern groove is formed by a damascene process.

7. A printed circuit board, comprising:
an insulating layer;
at least one plate through hole formed to penetrate through the insulating layer and filled with a conductive material; and
inner circuits buried in both surfaces of the insulating layer.

8. The printed circuit board according to claim 7, wherein the inner layer circuit includes a pattern groove filled with the same material as that filled in the plate through hole.

9. The printed circuit board according to claim 8, wherein the plate though hole and the pattern groove are filled with the conductive material by the same process.

10. The printed circuit board according to claim 7, wherein the conductive material includes a conductive paste or a conductive liquid.

11. The printed circuit board according to claim 10, wherein the conductive liquid includes copper ink.
